(19) United States
(12) Patent Application Publication
(10) Pub. No.: US 2007/0292987 A1
(43) Pub. Date: Dec. 20, 2007

(54) Method Of Fabricating Strained Thin Film Semiconductor Layer

(76) Inventors: Eui-Joon Yoon, Seoul (KR); Suk-Won Hong, Seoul (JP); Hyun-Ho Shin, Daejeon-city (JP)

Correspondence Address: LADAS & PARRY LLP, 224 SOUTH MICHIGAN AVENUE, SUITE 1600, CHICAGO, IL, 60604, US

(21) Appl. No.: 11/659,485

(22) PCT Filed: Mar. 22, 2005
(86) PCT No.: PCT/KR05/00816

§ 371 Date: Feb. 5, 2007

(30) Foreign Application Priority Data
Aug. 7, 2004 (KR) 10-2004-0062239

(51) Int. Cl. H01L 21/20

(52) U.S. Cl. 438/104; 438/492; 438/497; 257/E21.092

(57) ABSTRACT

A method of fabricating a strained thin film semiconductor layer having less dislocation and less defects than conventional methods, or no dislocation and no defects by controlling a stress distribution in a semiconductor substrate is provided. The method includes forming a trench in a semiconductor substrate, and epitaxially growing a first hetero thin film inside the trench, the first hetero thin film having a lattice constant different from that of the semiconductor substrate, thereby forming a stressor thereinside. Then, a second hetero thin film is made to be epitaxially grown on the semiconductor substrate having the stressor formed therein, in which the second hetero thin film, thereby forming a strained thin film semiconductor layer by a stress field of the stressor.

### TECHNICAL FIELD

The present invention relates to a method of fabricating a strained thin film semiconductor layer, and more particularly, to a method of fabricating a strained thin film semiconductor layer being usable as a virtual substrate.

### BACKGROUND ART

A virtual substrate is very useful in the industrial aspect because a thin film of an arbitrarily controllable lattice can be made to be grown on the virtual substrate. A conventional method of using such a virtual substrate is to form a lattice-relaxed semiconductor thin film, and then, form a new thin film thereon so that the lattice of the new thin film is strained in accordance with the virtual substrate. For example, when silicon (Si) is grown on a lattice-relaxed SiGe thin film on a Si substrate, a stress is applied to the Si so as to generate strain. As such, the strained Si is provided with many advantages such as mobility characteristic of electrons and holes. As the use of such a strained thin film semiconductor layer can reach a high performance device having characteristics of a high speed and a low power consumption, almost all fields of microelectronics are focused on the strained thin film semiconductor layer. Further, the strained thin film semiconductor layer allows to apply devices based on nitride, silicide, ferroelectric, III-V group compounds semiconductors and the like directly to an existing Si-based integration process, if the lattice constant of the strained thin film semiconductor layer can be controlled appropriately.

In order to make the strained thin film semiconductor layer acknowledged in its usefulness in the industry, several characteristic requirements must be satisfied. First, a strain extent of the strained lattice must be enough to apply a stress to the layer to be grown in a subsequent process. Secondly, a surface roughness of the strained thin film semiconductor layer must be low enough not to badly influence a photolithography process of the integration formation, and the like. If the surface roughness is low, the crystallinity of a thin film to be deposited thereon can be improved, and the adhesiveness between the thin films can be increased. Thirdly, the density of a dislocation deteriorating device characteristics must be lowered.

A typical method of forming a strained thin film semiconductor layer being used as a virtual substrate is to form a SiGe thin film on a Si substrate, and use a compositionally graded buffer layer increasing a Ge concentration gradually while forming the SiGe thin film concurrently. However, since the Ge concentration is increased gradually in the case of growing the compositionally graded buffer layer by the method, a stress will be applied to the compositionally graded buffer layer in the end so that the surface becomes rough due to the stress. As a result, it may cause problems in the high-integration formation processes for next-generation devices.

In order to maintain the surface roughness 10 nm or lower while using the conventional method, the thickness of the buffer layer must be increased up to 5 through 10 μm to loose the strain extent. In order to lower the surface roughness while not increasing the thickness of the buffer layer, a high-cost chemical mechanical polishing (CMP) process is necessary to planarize the surface.

### BRIEF DESCRIPTION OF THE DRAWINGS

FIGS. 1A through 1D are sectional views illustrating processing sequences of a method of fabricating a strained thin film semiconductor layer according to a first embodiment of the present invention.

FIG. 2 is a graph illustrating a critical thickness to form dislocation in accordance with a Ge concentration in the case of growing a SiGe thin film on a Si substrate.

FIGS. 3A through 3D are sectional diagrams illustrating detailed growth states and stress generation mechanism in the method of fabricating a strained thin film semiconductor layer according to the present invention.

FIGS. 4A through 4D are sectional views illustrating processing sequences of a method of fabricating a strained thin film semiconductor layer according to a second embodiment of the present invention.

FIGS. 5A through 5C are sectional views illustrating processing sequences of a method of fabricating a strained thin film semiconductor layer according to a third embodiment of the present invention.

FIGS. 6A and 6B illustrate the electronic simulation results to explain the alignment of stressors formed according to the present invention, the stressors formed thereby, and the calculation of a stress distribution formed around the stressors.

FIGS. 7A through 7C illustrate the electronic simulation results to explain alignment of stressors and calculation of stress distribution around the stressors, in which the stressor is different in shape from that of FIG. 6, and a lattice constant of the material filling the stressor is changed to vary the stress distribution.

FIGS. 8A and 8B illustrate the electronic simulation results to explain the case in which a thin film on the stressors shown in FIG. 7A is disconnected between two neighboring stressors, and the calculation of a stress distribution formed around them.

### DETAILED DESCRIPTION OF THE INVENTION TECHNICAL PROBLEM

The present invention provides a method of fabricating a strained thin film semiconductor layer having less dislocation and less defects than conventional methods, or no dislocation and no defects by controlling a stress distribution in a semiconductor substrate.

### Technical Solution

According to an aspect of the present invention, there is provided a method of fabricating a strained thin film semiconductor layer including forming a trench in a semiconductor substrate, and epitaxially growing a first hetero thin film inside the trench, the first hetero thin film having a lattice constant different from that of the semiconductor substrate, thereby forming a stressor thereinside. A second hetero thin film is epitaxially grown on the semiconductor substrate having the stressor formed therein, in which the second hetero thin film has a lattice constant different from that of the first hetero thin film, thereby forming a strained thin film semiconductor layer by a stress field of the stressor.

### Advantageous Effects

According to the present invention, a trench is formed in a semiconductor substrate, and a semiconductor material having a different lattice constant from that of the semiconductor substrate is epitaxially grown inside the trench with a thickness equal to a critical thickness or less, thereby forming a stressor filling the trench with a strained material without dislocation. Since the stressor has no dislocation and no defects, if another different semiconductor thin film is epitaxially grown on the semiconductor substrate having the stressor, a strained thin film semiconductor layer without dislocation and defects can be provided. The method has an advantage of providing a thin film without dislocation on the semiconductor substrate more easily in comparison with the conventional method, in which a very thick layer is formed to induce dislocation artificially and form lattice strains.

Further, even though dislocation occurs when a thickness of the material inside the trench becomes the critical thickness or more, an intrinsic stress field is generated between two neighboring stressors due to the difference of lattice constants. Also, in this case, if another semiconductor thin film is epitaxially grown on the semiconductor substrate having the stressors, lattice strains can be induced. Therefore, a strained thin film semiconductor layer can be formed more easily without dislocation than the conventional method.

### Best Mode

Preferably, the width and the depth of the trench may be determined equal to twice or less than a critical thickness to generate a dislocation in the first hetero thin film by the relationship between the semiconductor substrate and the first hetero thin film. For example, the width and the depth of the trench may be in the range of 10 nm through 100 μm. The formation of the trench may use an etch process such as photolithography and e-beam lithography.

The operation of forming a stressor includes growing the first hetero thin film from sidewalls of the trench so as to fill the trench, and planarizing the first hetero thin film formed on the semiconductor substrate using a chemical mechanical polishing (CMP) process. Alternatively, the operation of forming a stressor may include forming a barrier layer on an upper surface of the semiconductor substrate except for the trench, growing the first hetero thin film from sidewalls of the trench so as to fill the trench, and removing the barrier layer.

Preferably, the first hetero thin film may be grown using a material having a lattice constant higher than those of the semiconductor substrate and the second hetero thin film, and a portion of the second hetero thin film applied with a tensile stress by the stressor may be used as a device layer.

The semiconductor substrate may be a Si, Ge, GaAs, InP, GaN, InAs, GaP, Al₂O₃, or GaSb substrate, and the first hetero thin film may be a heterojunction layer including SiGe, SiC, SiGeC, InAlAs, InAlGaAs, InP, InGaAsP, InGaAs, GaAs, Si, GaN, AlN, or a mixture thereof. The second hetero thin film may be a heterojunction layer including SiGe, SiC, SiGeC, InAlAs, InAlGaAs, InP, InGaAsP, InGaAs, GaAs, Si, GaN, AlN, or a mixture thereof.

Further, two or more trenches may be formed, and a stress field by the stressor can be controlled by structurally controlling the shape of the trench and the alignment thereof. The method may further include etching a portion of the second hetero thin film between the stressors.

### Mode of Invention

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

### First Embodiment

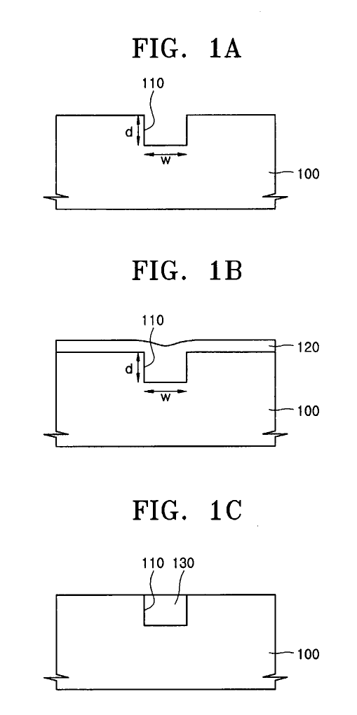

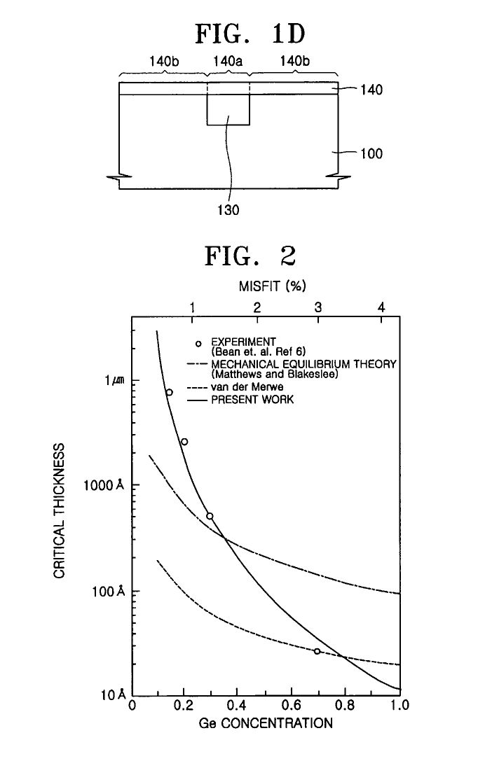

FIGS. 1A through 1D are sectional views illustrating processing sequences of a method of fabricating a strained thin film semiconductor layer according to a first embodiment of the present invention.

Referring to FIG. 1A, a trench 110 is formed in a semiconductor substrate 100. In order to form the trench 110, a photolithography process, an electron beam lithography process, and an etch process may be used. Here, the width w and the depth d of the trench 110 can be determined in consideration of a first hetero thin film 120 (FIG. 1 B), which will fill the trench 110 during a next subsequent process and has a lattice constant different from that of the semiconductor substrate 100, and in specific, twice or less the critical thickness to generate the dislocation in the first hetero thin film by the relationship between the first hetero thin film and the semiconductor substrate 100. For example, the width and the depth of the trench 110 may be determined in the range of 10 nm through 100 μm.

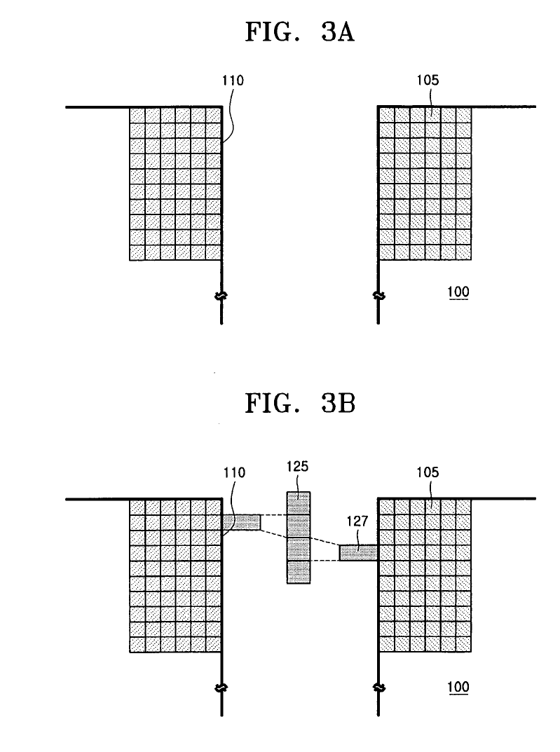

Here, the critical thickness means a thickness required to generate a dislocation between heterojunction materials, and is well known to those skilled in this art. If two materials to form the heterojunction are determined, the critical thickness can be provided by calculation (mechanical equilibrium theory, van der Merwe formula, etc.) or experiment. For example, in the case of growing a SiGe thin film on a Si substrate, the critical thickness to generate a dislocation in accordance with a Ge concentration can be provided by the graph of FIG. 2 (R. People et al., Appl. Phys. Lett., 47, 322 (1985)).

As such, in the case of epitaxially growing a material to form the heterojunction, when the material is grown with a thickness equal to or higher than a specific critical thickness, a dislocation is generated due to the difference of the lattice constants of two materials in order to remove the stress energy concentrated in the thin film. However, in the state that the thickness is equal to or less than the critical thickness, the lattice of the thin film material is just strained within the extent of being grown to maintain no-dislocation and no-defects. The embodiment of the present invention is intended to use the characteristic of the material to maintain no-dislocation and no-defects in the first hetero thin film by controlling the width w and the depth d of the trench 110 and thus, making the growth thickness of the first hetero thin film equal to or less than the critical thickness.

Then, the first hetero thin film 120 is epitaxially grown inside the trench 110 as shown in FIG. 1B, and the first hetero thin film 120 has a lattice constant different from that of the semiconductor substrate 100. For example, in the case that the semiconductor substrate 100 is a Si, Ge, GaAs, InP, GaN, InAs, GaP, Al₂O₃, or GaSb substrate, the first hetero thin film 120 is composed of SiGe, SiC, SiGeC, InAlAs, InAlGaAs, InP, InGaAsP, InGaAs, GaAs, Si, GaN, AlN, or a mixture thereof, so as to be grown as a heterojunction layer. A method of growing the first hetero thin film 120 may use e-beam evaporators, sublimation sources, Knudsen cell, an ion-beam deposition, an atomic layer epitaxy (ALE), a chemical vapor deposition (CVD), an atmospheric CVD (AP-CVD), a plasma enhanced CVD (PE-CVD), a rapid thermal CVD (RT-CVD), an ultra high vacuum CVD (UHV-CVD), a low pressure CVD (LP-CVD), a metalorganic CVD (MO-CVD), a chemical beam CVD (CB-CVD), a gas-source molecular beam epitaxy (GS-MBE), and the like. At this time, a buffer layer (not shown) may be further provided on the inner walls of the trench 110 before growing the first hetero thin film 120 in order to remove fine defects formed at the etch interface of the trench 110, and alleviate the surface roughness of the growth surface.

Preferably, since the first hetero thin film 120 is epitaxially grown from the sidewalls of the trench 110, and the width w and the depth d of the trench 110 are twice the critical thickness or less, the growth thickness of the first hetero thin film 120 starting from the sidewalls of the trench 110 becomes equal to or less than the critical thickness. Therefore, the inside of the trench 110 is filled with the first hetero thin film 120, which becomes strained along the growth direction, and has no dislocation or no defects therein.

Referring to FIG. 1B, the first hetero thin film 120 may be also grown on the semiconductor substrate 100. The first hetero thin film 120 grown on the semiconductor substrate 100 is planarized using a chemical mechanical polishing (CMP) as shown in FIG. 1C so that the first hetero thin film 120 is remained as a stressor 130 just inside the trench 110. Two or more trenches 110 can be formed in the state of FIG. 1A, and by structurally controlling the shape and the alignment of the trenches 110, a stress field by the stressor 130 can be controlled.

Then, referring to FIG.1D, a second hetero thin film 140 having a lattice constant different from that of the first hetero thin film 120 is epitaxially grown on the semiconductor substrate 100 having the stressor 130 formed therein. The second hetero thin film 140 is composed of two different portions due to the stress field by the stressor 130, that is, a portion 140a formed on the semiconductor substrate 100 and a portion 140b formed on the stressor 130, and the two portions have different lattice constants. That is, the second hetero thin film 140 forms a strained thin film semiconductor layer. In the case that the semiconductor substrate 100 is a Si, Ge, GaAs, InP, GaN, InAs, GaP, Al₂O₃, or GaSb substrate, and the first hetero thin film 120 is a heterojunction layer including SiGe, SiC, SiGeC, InAlAs, InAlGaAs, InP, InGaAsP, InGaAs, GaAs, Si, GaN, AlN, or a mixture thereof, the second hetero thin film 140 may be grown as a heterojunction layer including SiGe, SiC, SiGeC, InAlAs, InAlGaAs, InP, InGaAsP, InGaAs, GaAs, Si, GaN, AlN, or a mixture thereof. The semiconductor substrate 100 and the second hetero thin film 140 may be formed of a same material. A method of growing the second hetero thin film 140 may also use e-beam evaporators, sublimation sources, Knudsen cell, an ion-beam deposition, an ALE, and the like.

Conventionally, a virtual substrate was provided in such a manner that a hetero thin film is made to be grown on a substrate with a thickness equal to or higher than a critical thickness to generate dislocation and lattice relaxation, and then, another hetero thin film is made to be grown thereon to form a strained thin film semiconductor layer. However, in the embodiment of the present invention, since the width w of the trench 110 is controlled to be twice the critical thickness or less, the growth thickness on both sides of the trench 110 is limited less than the critical thickness to form dislocation. Thus, the inside of the trench 110 is finally filled with a semiconductor material of the first hetero thin film 120, which is strained along the growth direction. As a result, the stressor 130 can be formed with no dislocation and no defects, since the growth thickness is equal to or lower than the critical thickness. Further, if the second hetero thin film 140 as another semiconductor material having a different lattice constant is made to be grown on the semiconductor substrate 100 having the stressor 130, a thin film semiconductor layer can be formed with strained without dislocation and defects by the stress of the stressor 130.

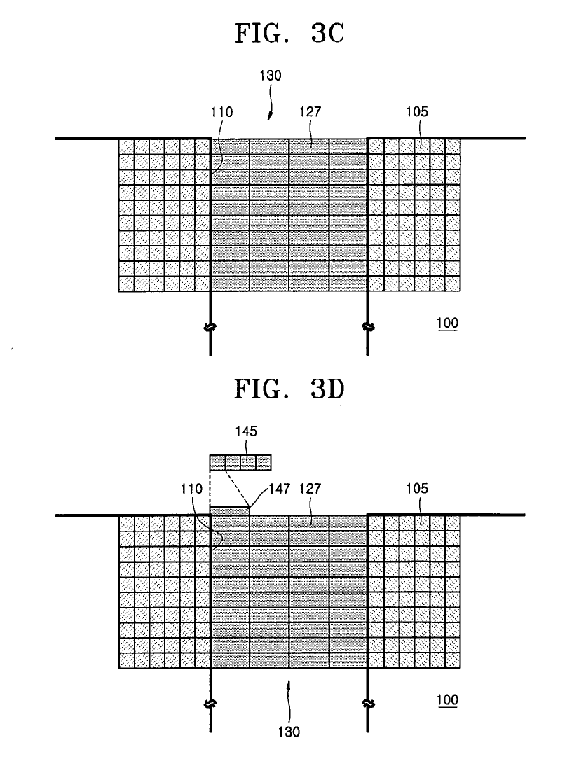

Referring to FIGS. 3A through 3D, specific growth states of the first hetero thin film 120 and the second hetero thin film 140, and stress generation mechanism thereof will be explained in more detail. The case illustrated in FIGS. 3A through 3D is that the lattice constant of the first hetero thin film 120 is higher than those of the semiconductor substrate 100 and the second hetero thin film 140.

First, FIG. 3A is an enlarged diagram illustrating the sectional view of the trench 110 near the surface of the semiconductor substrate 100. The semiconductor substrate 100 has a specific lattice constant as a crystalline structure, and can be represented symbolically as a substrate lattice 105.

FIG. 3B is a sectional diagram illustrating the state of epitaxially growing the first hetero thin film 120 on the semiconductor substrate 100. Since the material of the first hetero thin film 120 has a lattice constant higher than that of the semiconductor substrate 100, the first hetero thin film can be represented symbolically as an intrinsic lattice 125. In the case that the intrinsic lattice 125 of the first hetero thin film is grown on the substrate lattice 105, the intrinsic lattice 125 of the hetero semiconductor material is deformed in shape to a lattice 127, which is strained along the growth direction, at the initial epitaxial growth state, and the strained lattice 127 is adsorbed on the growth surface of the trench 110. In specific, the intrinsic lattice 125 of the first hetero thin film is applied with tensile stress in the lateral direction and compressive stress in the vertical direction, and thus, deformed in shape to the strained lattice 127.

As such, the growth is continuous, and the growth starting from one sidewall of the trench 110 comes to meet the growth starting from the other sidewall of the trench 110. FIG. 3C illustrates that the trench 110 is finally filled with a stressor 130 being composed of the stress-strained lattices 127 deformed from the intrinsic lattices 125 of the first hetero thin film. Further, as described above, in consideration of the lattice inconsistency between the substrate lattice 105 and the intrinsic lattice 125 of the first hetero thin film, the width and the depth of the trench 110 is controlled such that the growth from both sides is equal to or less than the critical thickness, that is, the width and the depth of the trench 110 are limited equal to twice the critical thickness or less. Thus, the intrinsic lattice 125 of the first hetero thin film is applied with a tensile stress without dislocation and defects, and changed to the strained lattice 127 having an increased lattice constant, so as to fill the trench 110.

FIG. 3D is a sectional diagram illustrating the state of epitaxially growing a second hetero thin film 140 on the semiconductor substrate 100 having the stressor 130. In this case, a material of the second hetero thin film 140 can be represented symbolically as an intrinsic lattice 145, having a lattice constant lower than that of the first hetero thin film 120. The intrinsic lattice 145 is coupled with the strained lattice 127 filling the trench 110 to be stress-strained, and is deformed in shape to a new lattice 147 extending in the lateral direction. On the contrary, if the first hetero thin film 120 has a lattice constant lower than those of the semiconductor substrate 100 and the second hetero thin film 140, it comes to be opposite to the above figures.

Therefore, the growth surface is formed inside the trench 110 with the strained lattice 127 having a different lattice constant, and the new strained structure functions as a virtual substrate to apply a tensile stress to the intrinsic lattice 145 of the second hetero thin film. Further, since the strained lattice 127 has no dislocation, the new lattice 147 can also maintain no-dislocation. Thus, the portion formed on the stressor 130 by the tensile stress, which is composed of the new lattices 147, can be used as a device layer. For example, if an MOS transistor channel is formed on the portion composed of the new lattices 147, a high speed transistor characteristic can be achieved using a high mobility of electrons.

### Second Embodiment

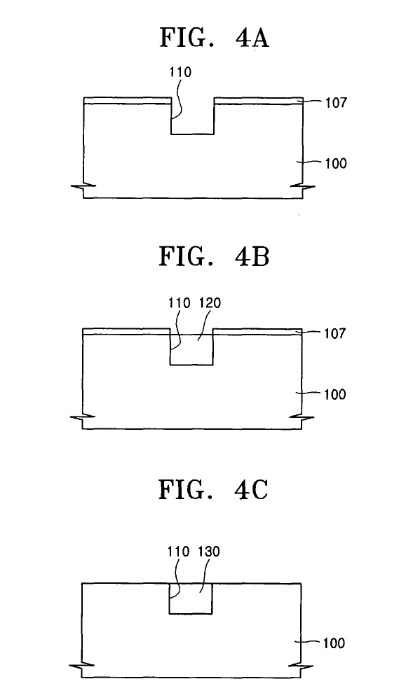

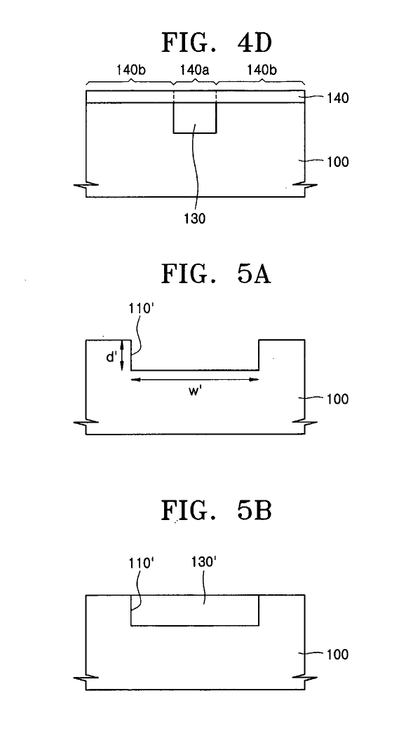

FIGS. 4A through 4D are sectional views illustrating processing sequences of a method of fabricating a strained thin film semiconductor layer according to a second embodiment of the present invention. Like elements of the first embodiment will refer to like numerals, and repeated description will be omitted.

Referring to FIG. 4A, a trench 110 is formed in a semiconductor substrate 100. A barrier layer 107 is formed on the semiconductor substrate 100 except for the trench 110. For example, after a silicon oxide layer is formed on the semiconductor substrate 100, the silicon oxide layer and the semiconductor substrate 100 are concurrently etched, thereby forming the trench 110 and the barrier layer 107 at one time. Alternatively, the semiconductor substrate 100 may be first etched to form the trench 110, and then, the silicon oxide layer may be formed only on the upper surface of the semiconductor substrate 100 with the inner walls of the trench 110 protected, thereby forming the barrier layer 107.

Then, a first hetero thin film 120 is made to be epitaxially grown inside the trench 110 as shown in FIG. 4B, to fill the trench 110. The first hetero thin film 120 is not grown on the upper surface of the semiconductor substrate 100 because of the existence of the barrier layer 107.

FIG. 4C illustrates the state that the barrier layer 107 is removed. If the barrier layer 107 is formed of a silicon oxide layer, it can be removed using a buffered oxide etchant (BOE) or HF diluted solution. Thus, a stressor 130 filling the trench 110 is formed.

Referring to FIG. 4D, a second hetero thin film 140 is made to be epitaxially grown on the semiconductor substrate 100 having the stressor 130 formed therein. The second hetero thin film 140 becomes a strained thin film semiconductor layer due to the stress field by the stressor 130.

In the second embodiment, since a process for CMP is not necessary during the formation of the stressor 130, fabrication costs is saved in comparison with the first embodiment.

### Third Embodiment

The first and second embodiments have described the cases in which the width w and the depth d of the trench 110 are twice the critical thickness or less. However, the width and the depth of the trench formed in the semiconductor substrate to form the stressor do not necessarily satisfy the conditions. In this embodiment, the case in which the width and the depth of the trench are twice the critical thickness or more will be taken as an example.

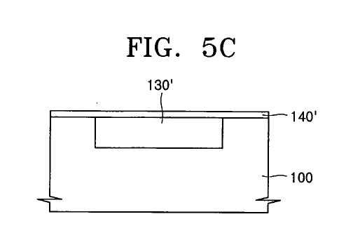

FIGS. 5A through 5C are sectional views illustrating processing sequences of a method of fabricating a strained thin film semiconductor layer according to a third embodiment of the present invention. Like elements of the first embodiment will refer to like numerals, and repeated description will be omitted.

Referring to FIG. 5A, a trench 110′ is formed in a semiconductor substrate 100. There is no limitation in the width w′ and the depth d′ of the trench 110′. However, for comparison with the first and second embodiments, the width w′ and the depth d′ of the trench 110′ can be determined in consideration of a first hetero thin film, which will fill the trench 110′ during a next subsequent process and has a lattice constant different from that of the semiconductor substrate 100, and in specific, twice or more the critical thickness to generate the dislocation in the first hetero thin film by the relationship between the first hetero thin film and the semiconductor substrate 100.

Then, referring to FIG. 5B, the first hetero thin film is made to be epitaxially grown to fill the trench 110′, thereby forming a stressor 130′. The formation of the stressor 130′ may use the CMP process like the first embodiment, or the barrier layer like the second embodiment.

FIG. 5C illustrates that a second hetero thin film 140′ is made to be epitaxially grown on the semiconductor substrate 100 having the stressor 130′ formed therein, and the second hetero thin film 140′ has a lattice constant different from that of the first hetero thin film. The second hetero thin film 140′ becomes a strained thin film semiconductor layer due to the stress field by the stressor 130′.

In this embodiment, since the width w′ and the depth d′ of the trench 110′ are twice the critical thickness or more, if the growth thickness of the first hetero thin film growing on the sidewalls of the trench 110′ becomes equal to the critical thickness or more, dislocation is generated in the stressor 130′ inside the trench 110′. The generation of the dislocation means that a portion of the lattice filling the trench 110′ comes back to the intrinsic lattice of the first hetero thin film material constituting the stressor 130′ during the stress relaxation. However, in this case, a stress field may be generated due to the difference of lattice constants since the intrinsic lattice constant of the first hetero thin film material is different from that of the semiconductor substrate 100. Thus, even in the case that the dislocation is generated, the lattice constant may be changed if the second hetero thin film 140′ is made to be grown on the stressor 130′.

Furthermore, a stress field outside the stressor 130′ can be formed through appropriate arrangement of the stressors 130′ to grow the second hetero thin film 140′ thereon. At this time, the first hetero thin film is made to be grown using a material having a lattice constant lower that those of the semiconductor substrate 100 and the second hetero thin film 140′, so as to generate a tensile stress to the second hetero thin film 140′ formed on the semiconductor substrate 100 outside the stressor 130′. Thus, the portion of the second hetero thin film 140′ applied with the tensile stress can be used as a device layer.

In another example, even though the dislocation may occur in the stressor 130′, the possibility of the dislocation is high at the interface where two portions of the first hetero thin film growing from both sidewalls of the trench 110′ meet, that is, the middle portion of the trench 110′, a portion of the second hetero thin film 140′ formed on the stressor 130′ except for the middle portion of the trench 110′ may be used as a device layer.

More detailed description of the present invention will be explained by following specific experiment examples. As even the contents, which have not been described here, can be well understood to those skilled in this art, the description thereon will be omitted. Further, following experiment examples are not intended to limit the scope of the present invention.

### Experiment Example

A mask patterning is performed on a Si (001) substrate using an electron-beam lithography process and a dry etch using plasma is performed, thereby forming a trench with a size of 100 nm×100 nm×100 nm. Here, the width of the trench is determined as 100 nm, twice or less the critical thickness of a Si_{0.8}Ge_{0.2} layer to fill the trench in order to provide a stressor without dislocation. After removing the mask, a Si buffer layer with a thickness of 10 nm is made to be grown on the Si substrate having the trench, using UHV-CVD at a temperature of 650° C. The buffer layer functions to prepare a surface for epitaxial growth by alleviating the surface roughness of the Si substrate surface and the growth surface inside the trench, and covering fine defects. After the buffer layer is formed, a Si_{0.8}Ge_{0.2} layer is grown with a thickness of 50 nm at a temperature of 450° C. so as to fill the trench with a width of 100 nm. While the Si_{0.8}Ge_{0.2} layer is epitaxially grown inside the trench, the epitaxial growth occurs on the surface of the Si substrate, and the layer formed thereby causes the generation of dislocation because of inconsistency between the layer and the Si substrate lattice. In order to remove the layer and expose the Si_{0.8}Ge_{0.2} layer inside the trench, the surface is planarized using CMP. Thus, a stressor of the Si_{0.8}Ge_{0.2} layer is remained inside the trench, and a Si layer is grown thereon at a low temperature of 500° C. As a result, the Si layer on the stressor is applied with a tensile stress from the stressor so that the lattice constant of the layer is increased.

The generation of the stress field formed by the method of fabricating a strained thin film semiconductor layer according to the present invention and the control thereof can be explained through specific electronic simulation experiment examples.

Electronic Simulation 1

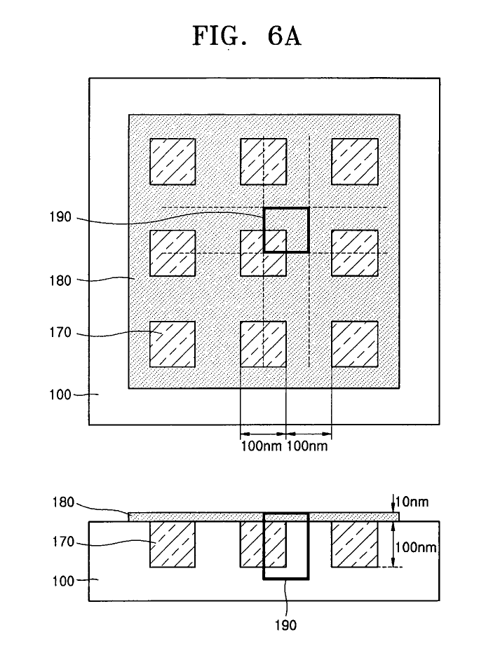

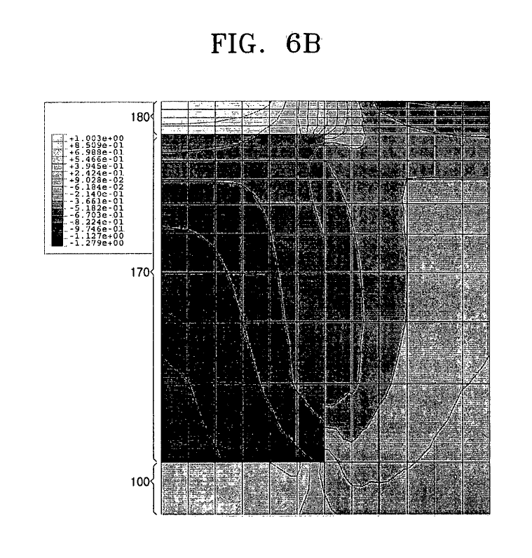

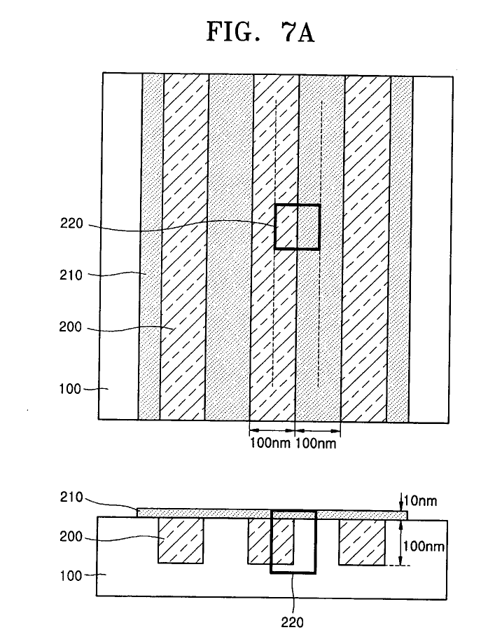

FIGS. 6A and 6B illustrate the electronic simulation results to explain the alignment of stressors formed according to the present invention, the stressors formed thereby, and the calculation of a stress distribution formed around the stressors.

First, FIG. 6A illustrates the alignment of the stressors 170 composed of a Si_{0.8}Ge_{0.2} layer filling the trenches of the Si substrate 100 and having a higher lattice constant than that of the Si substrate 100, at the upper surface and the section of the Si substrate 100 respectively.

In the electronic simulation 1 of FIG. 6A, it is assumed that the stressor 170 is formed in the Si substrate in the trench with a size of 100 nm×100 nm×100 nm by filling the Si_{0.8}Ge_{0.2} layer thereinside, and the distance between the stressors is 100 nm. Then, it is assumed that a Si thin film 180 is grown thereon with a thickness of 10 nm. The area placed for the electronic simulation is an area 190, and the portion ¼ the area is disposed on the stressor 170 as shown in FIG. 6A

FIG. 6B illustrates the simulation results of FIG. 6A. The dark portion of the drawing represents a compressive stress, and the bright portion represents a tensile stress. As shown in the stress distribution in the calculated area, a tensile stress is applied to the region of the Si thin film 180 having the stressor 170 there below, and the extent of the applied tensile stress is being reduced toward the boundary of the stressor 170. On the contrary, a compressive stress is applied to the region away from the stressor 170 by 50 nm, that is, the middle of neighboring two stressors 170. The compressive stress is balanced with the tensile stress by the stressor 170. The compressive stress is caused by a peripheral stress field, not by the heterojunction, which means that the stress-applied region between the neighboring stressors 170 without dislocation can be controlled, regardless of the generation of dislocation in the stressor 170.

Electronic Simulation 2

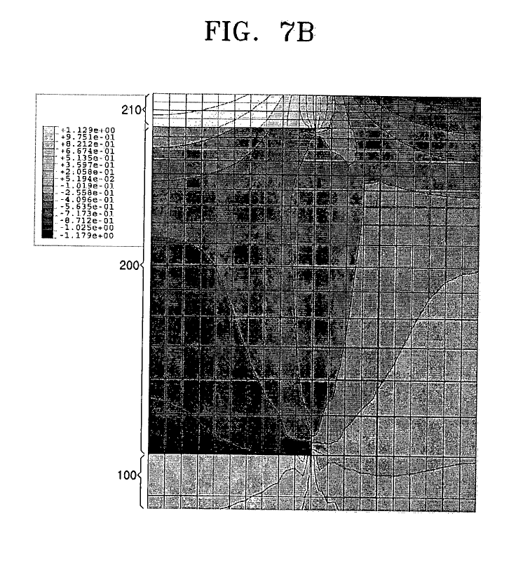

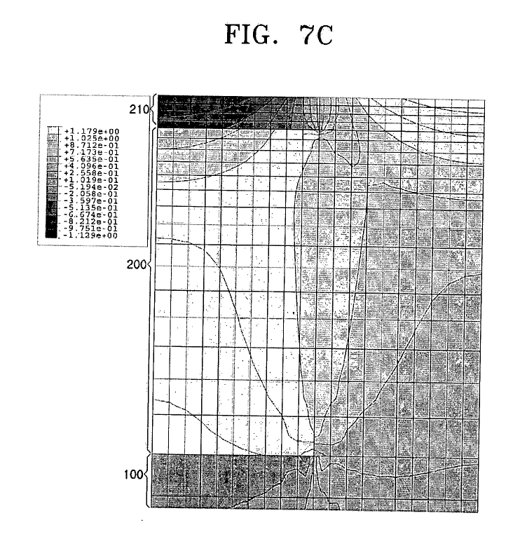

FIGS. 7A through 7C illustrate the electronic simulation results to explain alignment of stressors and calculation of stress distribution around the stressors, in which the stressor is different in shape from that of FIG. 6, and a lattice constant of the material filling the stressor is changed to vary the stress distribution.

The case of FIG. 7A shows that line-shaped stressors 200 are aligned while the case of FIG. 6A shows that square-shaped stressors 170 are aligned. Referring to FIG. 7A, it is assumed that the stressors 200 are formed by aligning line-shaped trenches in a Si substrate 100 with a distance of 100 nm between two neighboring stressors, each trench having a width of 100 nm and a depth of 100 nm, and by filling the trenches with a hetero thin film material. In order to calculate stress distributions applied to a Si thin film 210 being grown on the stressor 200 in two cases in which the lattice constant of the material filling the stressor 200 is higher and lower than that of the semiconductor substrate 100 respectively, a first case assumes that the stressor 200 applies a tensile stress after the trench is filled with Si_{0.8}Ge_{0.2} having a higher lattice constant than that of the Si substrate 100, and a second case assumes that the stressor 200 applies a compressive stress having the same dimension as the tensile stress of the first case but opposite signal after the trench is filled with Si_{0.8}Ge_{0.2} having a same mechanical property. Further, it is assumed that the Si thin film 210 with a thickness of 10 nm is grown on the overall surface of the Si substrate 100 having the stressors 200 in both two cases. The area placed for the electronic simulation is an area 220, and the area is 100 nm×100 nm in size. Thus, the portion ½ the area is disposed on the stressor 200.

FIG. 7B illustrates the electronic simulation result of the first case in which the stressor 200 applies a tensile stress, and FIG. 7C illustrates the electronic simulation result of the second case in which the stressor 200 applies a compressive stress. In FIGS. 7B and 7C, the dark portion of the drawing represents a compressive stress, and the bright portion represents a tensile stress.

As shown in FIGS. 7B and 7C, in the case of forming the stressor 200 using a material having a lattice constant higher (lower) than that of the Si substrate 100, the Si thin film 210 grown thereon is applied with a tensile (compressive) stress, and thus, the calculation results are shown by bright ( dark) shade. However, a compressive (tensile) stress is applied to the region away from the stressor 200 by 50 nm, that is, the middle of two neighboring stressors 200. In the region, the compressive (tensile) stress is applied to the Si thin film 210, in order to balance with the tensile (compressive) stress by the stressor 200. Thus, the calculation result is shown as dark ( bright) shade in the Si thin film 210. The result as above is shown regardless of the generation of dislocation in the stressor 200. Even though dislocation is generated, and the material lattice inside the stressor 200 comes back to the intrinsic lattice, stress distribution comes to still exist around the stressor 200 due to the lattice constant difference between the intrinsic lattice constant of the Si substrate 100 and the intrinsic lattice constant of the material filling the stressor 200. Therefore, the Si thin film 210 between the two neighboring stressors 200 comes to be strained without dislocation.

In comparison of the result of FIGS. 7B and 7C (electronic simulation 2) with the result of FIG. 6B (electronic simulation 1), it is found that the stress is higher in magnitude in the case of FIGS. 7B and 7C. This is because the stressor 200 in the electronic simulation 2 is line-shaped while the stressor 170 in the electronic simulation 1 is square-shaped, and thus, the number of the neighboring stressors in the electronic simulation 2 to provide the stress balance is smaller than that in the electronic simulation 1.

As known by the electronic simulations 1 and 2 as above, the stress between the neighboring stressors is finally applied to the grown thin film with opposite signal to that of the stress on the stressors in order to achieve the stress balance on the overall surface of the thin film. Further, the impact by the stressors during the process of forming the stress balance is limited to 60% the area of the stressors.

Electronic Simulation 3

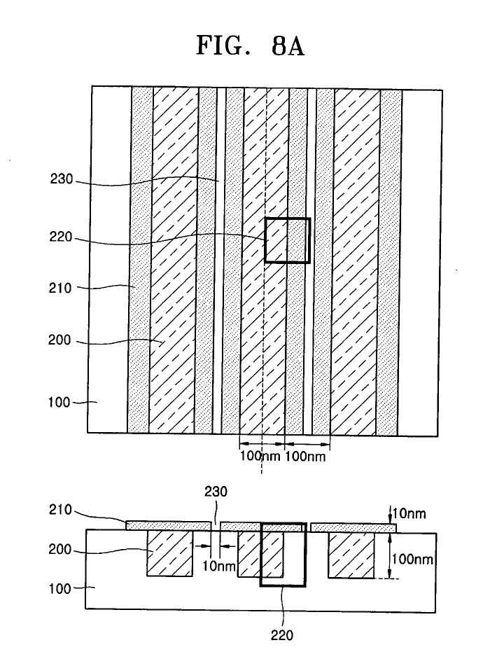

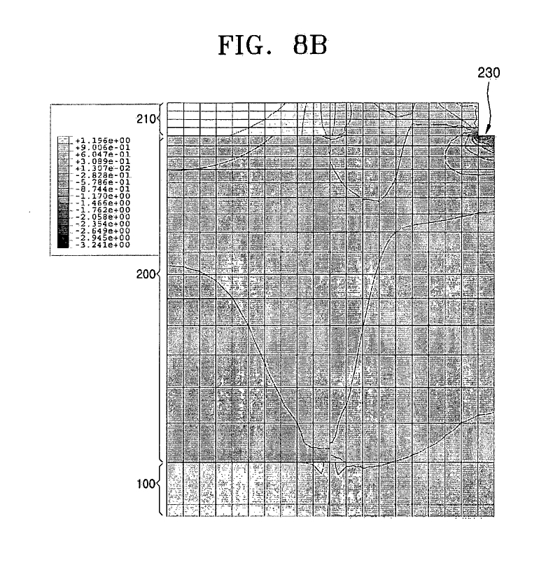

FIGS. 8A and 8B illustrate the electronic simulation results to explain the case in which a thin film on stressors shown in FIG. 7A is disconnected between two neighboring stressors, and the calculation of a stress distribution formed around them.

Referring to FIG. 8A, it is assumed that stressors are formed by aligning line-shaped trenches in a Si substrate 100 with a distance of 100 nm between two neighboring stressors, each trench having a width of 100 nm and a depth of 100 nm, and by filling the trenches with Si_{0.8}Ge_{0.2}. Further, it is assumed that a Si thin film 210 with a thickness of 10 nm is grown on the overall surface of the Si substrate 100 having the stressors 200. Further, it is assumed that the Si thin film portion between the two neighboring stressors 200 is removed with a depth of 10 nm to form a trench 230, thereby disconnecting the thin film between the stressors 200. The area placed for the electronic simulation is an area 220, and the area is 100 nm×100 nm in size. Thus, the portion ½ the area is disposed on the stressor 200.

FIG. 8B illustrates the result of the stress distribution. From the drawing, it is found that a portion of the Si thin film 210 on the stressor 200, which is applied with a tensile stress, corresponds to about 90% the area of the stressor 200. Also, a stress is not found in a portion between two neighboring stressors 200 by the presence of the trench 230. That is, the opposite-signal stress generated between the two neighboring stressors 200 is removed by the trench 230 so that the strain by the stressor 200 can be more effectively provided than in the cases of the electronic simulations 1 and 2.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of fabricating a strained thin film semiconductor layer comprising:
forming a trench in a semiconductor substrate;
epitaxially growing a first hetero thin film inside the trench, the first hetero thin film having a lattice constant different from that of the semiconductor substrate, thereby forming a stressor thereinside; and
epitaxially growing a second hetero thin film on the semiconductor substrate having the stressor formed therein, the second hetero thin film having a lattice constant different from that of the first hetero thin film, thereby forming a strained thin film semiconductor layer by a stress field of the stressor.

2. The method according to claim 1, wherein the width and the depth of the trench are determined equal to twice or less than a critical thickness to generate a dislocation in the first hetero thin film by the relationship between the semiconductor substrate and the first hetero thin film.

3. The method according to claim 1, wherein a depth of the trench is determined to an extent that growth on a bottom surface of the trench does not influence lattice strain on a surface of the semiconductor substrate.

4. The method according to claim 1, wherein the width and the depth of the trench are in the range of 10 nm through 100 μm.

5. The method according to claim 1, wherein the operation of forming a stressor comprises:
growing the first hetero thin film from sidewalls of the trench so as to fill the trench; and
planarizing the first hetero thin film formed on the semiconductor substrate using a chemical mechanical polishing (CMP) process.

6. The method according to claim 1, wherein the operation of forming a stressor comprises:
forming a barrier layer on an upper surface of the semiconductor substrate except for the trench;
growing the first hetero thin film from sidewalls of the trench so as to fill the trench; and
removing the barrier layer.

7. The method according to claim 1, wherein the first hetero thin film is made to be grown using a material having a lattice constant higher than those of the semiconductor substrate and the second hetero thin film, and a portion of the second hetero thin film applied with a tensile stress by the stressor is used as a device layer.

8. The method according to claim 1, wherein the semiconductor substrate is a Si, Ge, GaAs, InP, GaN, InAs, GaP, Al₂O₃, or GaSb substrate.

9. The method according to claim 8, wherein the first hetero thin film is a heterojunction layer including SiGe, SiC, SiGeC, InAlAs, InAlGaAs, InP, InGaAsP, InGaAs, GaAs, Si, GaN, AlN, or a mixture thereof.

10. The method according to claim 9, wherein the second hetero thin film is a heterojunction layer including SiGe, SiC, SiGeC, InAlAs, InAlGaAs, InP, InGaAsP, InGaAs, GaAs, Si, GaN, AlN, or a mixture thereof.

11. The method according to claim 1, wherein two or more trenches are formed, and a stress field by the stressor is controlled by structurally controlling the shape of the trench and the alignment thereof.

12. The method according to claim 11, further comprising etching a portion of the second hetero thin film between the stressors.

13. The method according to claim 2, wherein the operation of forming a stressor comprises:
growing the first hetero thin film from sidewalls of the trench so as to fill the trench; and
planarizing the first hetero thin film formed on the semiconductor substrate using a CMP process.

14. The method according to claim 2, wherein the operation of forming a stressor comprises:
forming a mask on an upper surface of the semiconductor substrate except for the trench;
growing the first hetero thin film from sidewalls of the trench so as to fill the trench; and
removing the mask.

15. The method according to claim 2, wherein the first hetero thin film is made to be grown using a material having a lattice constant higher than those of the semiconductor substrate and the second hetero thin film, and a portion of the second hetero thin film applied with a tensile stress by the stressor is used as a device layer.

16. The method according to claim 2, wherein the semiconductor substrate is a Si, Ge, GaAs, InP, GaN, InAs, GaP, Al₂O₃, or GaSb substrate.

17. The method according to claim 16, wherein the first hetero thin film is a heterojunction layer including SiGe, SiC, SiGeC, InAlAs, InAlGaAs, InP, InGaAsP, InGaAs, GaAs, Si, GaN, AlN, or a mixture thereof.

18. The method according to claim 17, wherein the second hetero thin film is a heterojunction layer including SiGe, SiC, SiGeC, InAlAs, InAlGaAs, InP, InGaAsP, InGaAs, GaAs, Si, GaN, AlN, or a mixture thereof.

19. The method according to claim 2, wherein two or more trenches are formed, and a stress field by the stressor is controlled by structurally controlling the shape of the trench and the alignment thereof.

20. The method according to claim 19, further comprising etching a portion of the second hetero thin film between the stressors.
